(19) United States
(12) Patent Application Publication
(10) Pub. No.: US 2007/0294870 A1
(43) Pub. Date: Dec. 27, 2007

(54) Multi-stage flow control apparatus and method of use

(75) Inventors: Ming-Kuei Tseng, San Jose, CA (US); Kim Vellore, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/475,365

(22) Filed: Jun. 27, 2006

(51) Int. Cl. H01L 21/67

(52) U.S. Cl. 29/25.01

(57) ABSTRACT

A multi-stage flow control apparatus for use during the processing of a semiconductor substrate is provided. The multi-stage flow control apparatus includes a first inlet and a second inlet, an outlet, and a first throttle valve stage coupled to the first inlet. The first throttle valve stage includes a first throttle valve plug located within the first throttle valve stage. The first throttle valve plug is configured to control the amount of airflow through the first throttle valve stage by modulating the distance between the first throttle valve plug and faces of the first throttle valve stage. The multi-stage flow control apparatus further includes a second throttle valve stage coupled to the second inlet. The second throttle valve stage includes a second throttle valve plug located within the second throttle valve stage. The second throttle valve plug is configured to control the amount of airflow through the second throttle valve stage by modulating the distance between the second throttle valve plug and faces of the second throttle valve stage. In addition, the multi-stage flow control apparatus includes a floating plunger stage coupled to the throttle valve stage.

### CROSS-REFERENCES TO RELATED APPLICATIONS

The following three regular U.S. patent applications (including this one) are being filed concurrently, and the entire disclosure of the other applications is incorporated by reference into this application for all purposes:

U.S. patent application Ser. No. ______, filed ______, in the names of Michael Tseng and Kim Vellore, titled, “Multi-Stage Flow Control Apparatus and Method of Use,” (Attorney Docket Number 016301-064800US);

U.S. patent application Ser. No. ______, filed ______, in the name of Michael Tseng, titled, “Multi-Stage Flow Control Apparatus with Flexible Membrane and Method of Use,” (Attorney Docket Number 016301-064900US); and

U.S. patent application Ser. No. ______, filed ______, in the name of Michael Tseng, titled, “Multi-Stage Flow Control Apparatus,” (Attorney Docket Number 016301-065000US).

### BACKGROUND OF THE INVENTION

The present invention relates generally to the field of substrate processing equipment. More particularly, the present invention relates to an apparatus for maintaining a constant exhaust flow through one or more exhaust lines coupled to semiconductor processing chambers. Merely by way of example, the invention can be applied by using a multi-stage flow control apparatus to control and regulate the exhaust flow. The method and apparatus can be applied to other devices for processing semiconductor substrates, for example those used in the formation of integrated circuits.

Modern integrated circuits contain millions of individual elements that are formed by patterning the materials, such as silicon, metal and/or dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that substrates processed within the chambers of the track lithography tool undergo repeatable processing steps. Thus, process engineers will typically monitor and control the device fabrication processes to ensure repeatability from substrate to substrate.

Semiconductor processing chambers used in device fabrication processes are commonly coupled with exhaust devices to maintain desired pressure levels within the processes and to evacuate the chambers of undesired materials. For example, gases used within device fabrication processes may be evacuated at the conclusion of the processes by using an exhaust device coupled to the semiconductor processing chamber by an exhaust line. However, one problem that can occur is that a varying exhaust flow from the exhaust line can affect the lithography uniformity by disrupting the air flow within the processing bowl. For example, back streaming of the house exhaust into the bowls can affect cause variations within the air flow through the bowl and thus reduce the uniformity of lithography processes performed in the semiconductor processing chamber.

In view of these requirements, methods and techniques are needed to eliminate fluctuations in house exhaust and prevent back streaming of house exhaust into the bowl for semiconductor fabrication processes.

### BRIEF SUMMARY OF THE INVENTION

According to the present invention, methods and apparatus related to semiconductor manufacturing equipment are provided. More particularly, the present invention relates to an apparatus for maintaining a constant exhaust flow through exhaust lines coupled to two or more semiconductor processing chambers. Merely by way of example, the invention can be applied by using a multi-stage flow control apparatus to control and regulate the exhaust flow. While some embodiments of the invention are particularly useful in eliminating fluctuations and back streaming of house exhaust for one or more lithography chambers, other embodiments of the invention can be used in other applications where it is desirable to manage air flow in a highly controllable manner.

According to an embodiment of the present invention, a multi-stage flow control apparatus for use in semiconductor manufacturing is provided. The multi-stage flow control apparatus includes a first inlet and a second inlet, an outlet, and a first throttle valve stage coupled to the first inlet. The first throttle valve stage includes a first throttle valve plug located within the first throttle valve stage. The first throttle valve plug is configured to control the amount of airflow through the first throttle valve stage by modulating the distance between the first throttle valve plug and faces of the first throttle valve stage. The multi-stage flow control apparatus further includes a second throttle valve stage coupled to the second inlet. The second throttle valve stage includes a second throttle valve plug located within the second throttle valve stage. The second throttle valve plug is configured to control the amount of airflow through the second throttle valve stage by modulating the distance between the second throttle valve plug and faces of the second throttle valve stage. In addition, the multi-stage flow control apparatus includes a floating plunger stage coupled to the throttle valve stage.

In another embodiment of the present invention, a flow control apparatus is provided. The flow control apparatus includes a first chamber having an inlet and an outlet and a second chamber having an inlet and an outlet. The flow control apparatus further includes a third chamber having at least two inlets and an outlet. A first inlet of the third chamber is coupled to the outlet of the first chamber and a second inlet of the third chamber is coupled to the outlet of the second chamber. The flow control apparatus additionally includes a first throttle valve operatively coupled to restrict airflow through the first chamber and a second throttle valve operatively coupled to restrict airflow through the second chamber. Furthermore, the flow control apparatus includes a floating plunger coupled to restrict airflow through the third chamber. A surface of the floating plunger receives a controlled pressure that allows the floating plunger to move in a controlled manner.

In another embodiment of the present invention, a track lithography tool is provided. The track lithography tool includes first and second semiconductor processing chambers, and first and second exhaust outputs. The first semiconductor processing chamber is coupled to the first exhaust output and the second semiconductor processing chamber is coupled to the second exhaust output. The track lithography tool further includes an exhaust device and a multi-stage flow control apparatus. The multi-stage flow control apparatus includes a first chamber having an inlet and an outlet and a second chamber having an inlet and an outlet. The multi-stage flow control apparatus also includes a third chamber having at least two inlets and an outlet. A first inlet of the third chamber is coupled to the outlet of the first chamber and a second inlet of the third chamber is coupled to the outlet of the second chamber. The multi-stage flow control apparatus additionally includes a first throttle valve operatively coupled to restrict airflow through the first chamber and a second throttle valve operatively coupled to restrict airflow through the second chamber. Furthermore, the multi-stage flow control apparatus includes a floating plunger coupled to restrict airflow through the third chamber. A surface of the floating plunger receives a controlled pressure that allows the floating plunger to move in a controlled manner.

In another embodiment of the present invention, a method of operating a multi-stage flow control apparatus is provided. The method includes providing at least one exhaust flow through the multi-stage flow control apparatus from a first semiconductor processing chamber to an exhaust device. Furthermore, the method includes determining a first set point for the first semiconductor processing chamber in a first throttle valve stage. In addition, the method includes determining a second set point for the second semiconductor processing chamber in a second throttle valve stage. The method additionally includes detecting a change in the at least one exhaust flow or pressure in the multi-stage flow control apparatus. The method also includes varying the position of a floating plunger to modify the at least one exhaust flow or pressure in the multi-stage flow control apparatus. The method additionally includes rechecking the at least one exhaust flow and pressure in the multi-stage flow control apparatus. Furthermore, the method includes having the at least one exhaust flow and pressure return to an equilibrium flow level.

Many benefits are achieved by way of the present invention over conventional techniques. For example, an embodiment of the present invention provides a dual output design which provides set points for two or more chambers. For bowl designs with shared dispense or other twin designs, pressure and exhaust flow in each chamber is independently controlled by a throttle valve. A plunger may be shared by the two throttle valves to reduce the footprint and system cost. Additionally, the methods and apparatus of the present invention provide a method of reducing fluctuations in house exhaust and prevent back streaming of house exhaust. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of an embodiment of a track lithography tool according to an embodiment of the present invention;

FIG. 2 is a simplified cross-sectional diagram of a multi-stage flow control apparatus according to an embodiment of the present invention;

FIG. 3 is a simplified perspective view of a multi-stage flow control apparatus according to an embodiment of the present invention;

FIG. 4 is a simplified cross-sectional diagram of an multi-stage flow control apparatus according to an additional embodiment of the present invention;

FIG. 5 is a simplified exemplary diagram showing exhaust pressure with and without a multi-stage flow control apparatus according to an embodiment of the present invention;

FIG. 6 is a simplified exemplary process flow showing processes used to maintain a constant exhaust flow according to an embodiment of the present invention;

FIG. 7 is a simplified cross-sectional diagram of a multi-stage flow control apparatus according to an embodiment of the present invention;

FIG. 8 is a simplified perspective view of a multi-stage flow control apparatus according to an embodiment of the present invention;

FIG. 9 is a simplified cross-sectional diagram of a multi-stage flow control apparatus according to another embodiment of the present invention; and

FIG. 10 is a simplified exemplary process flow showing processes used to maintain a constant exhaust flow according to another embodiment of the present invention.

### DETAILED DESCRIPTION OF THE INVENTION

According to the present invention, an apparatus related to semiconductor manufacturing equipment are provided. More particularly, the present invention relates to an apparatus for maintaining a constant exhaust flow through exhaust lines coupled to semiconductor processing chambers. Merely by way of example, the invention can be applied by using a multi-stage flow control apparatus to control and regulate the exhaust flow. While some embodiments of the invention are particularly useful in eliminating fluctuations and back streaming of house exhaust for one or more lithography chambers, other embodiments of the invention can be used in other applications where it is desirable to manage air flow in a highly controllable manner.

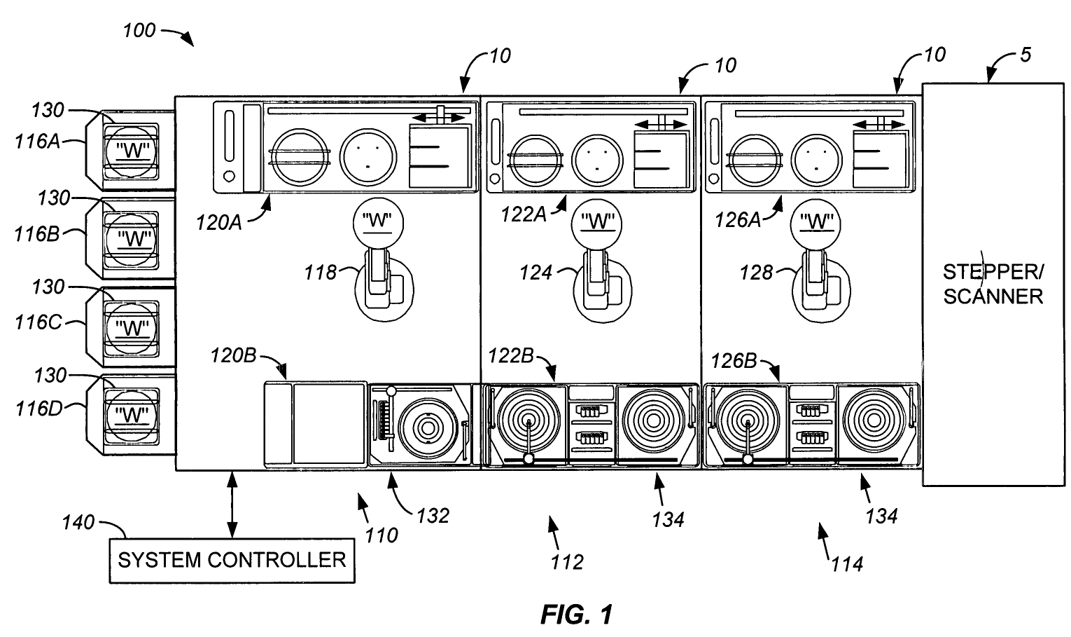

FIG. 1 is a plan view of an embodiment of a track lithography tool 100 in which the embodiments of the present invention may be used. As illustrated in FIG. 1, track lithography tool 100 contains a front end module 110 (sometimes referred to as a factory interface or FI) and a process module 111. In other embodiments, the track lithography tool 100 includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers, “W,” that are to be processed in track lithography tool 100. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of nozzles 123 providing processing fluids (e.g., bottom anti-reflection coating (BARC) liquid, resist, developer, and the like) to a wafer mounted on a substrate support 127 located in the coat bowl 121. In the embodiment illustrated in FIG. 1, a dispense arm 125 sliding along a track 126 is able to pick up a nozzle 123 from the shared dispense bank 122 and position the selected nozzle over the wafer for dispense operations. Of course, coat bowls with dedicated dispense banks are provided in alternative embodiments.

Processing rack 130 includes an integrated thermal unit 134 including a bake plate 131, a chill plate 132, and a shuttle 133. The bake plate 131 and the chill plate 132 are utilized in heat treatment operations including post exposure bake (PEB), post-resist bake, and the like. In some embodiments, the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments, the shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move in a vertical (z-direction) and horizontal directions, i.e., transfer direction (x-direction) and a direction orthogonal to the transfer direction (y-direction). Utilizing one or more of these three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool 100, robot assembly 140A and robot assembly 140B are similarly configured and include at least one horizontal motion assembly 142, a vertical motion assembly 144, and a robot hardware assembly 143 supporting a robot blade 145. Robot assemblies 140 are in communication with a system controller 160. In the embodiment illustrated in FIG. 1, a rear robot assembly 148 is also provided.

The scanner 150, which may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner 150 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, a system controller 160 is used to control all of the components and processes performed in the cluster tool 100. The controller 160 is generally adapted to communicate with the scanner 150, monitor and control aspects of the processes performed in the cluster tool 100, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chamber(s). Preferably, the program is software readable by the controller 160 and includes instructions to monitor and control the process based on defined rules and input data.

Referring to FIG. 1, a variable process module 198 is provided in the track lithography tool 100. Variable process module 198 is serviced by one or both of the robot assemblies 140. The use of the variable process module may occur before or after several of the wafer processes performed within the track lithography tool 100. These wafer processes include coat, develop, bake, chill, exposure, and the like. In a particular embodiment, variable process module may be used for wafer particle detection, or for performing one or more of the wafer processes described above. One of ordinary skill in the art would recognize many variations, modifications, and alternatives.

It is to be understood that embodiments of the invention are not limited to use with a track lithography tool such as that depicted in FIG. 1. Instead, embodiments of the invention may be used in any track lithography tool including the many different tool configurations described in U.S. patent application Ser. No. 11/315,984, entitled “Cartesian Robot Cluster Tool Architecture” filed on Dec. 22, 2005, which is hereby incorporated by reference for all purposes and including configurations not described in the above referenced application.

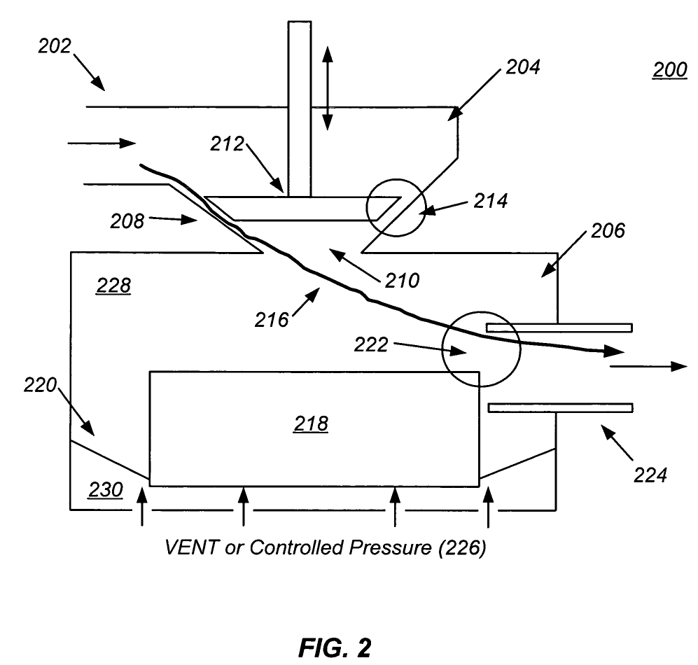

FIG. 2 is a simplified cross-sectional diagram of a multi-stage flow control apparatus according to an embodiment of the present invention. This diagram is merely an example, which should not unduly limit the scope of the claims herein. One of ordinary skill in the art would recognize many other variations, modifications, and alternatives. A multi-stage flow control apparatus 200 is provided for use between a semiconductor processing chamber (not shown) and an exhaust device (not shown). For example, the semiconductor processing chamber may be a lithography device including one or more bowls used within lithography processing steps such as a track lithography tool described in FIG. 1. In another example, the exhaust device may be house exhaust present in a semiconductor manufacturing facility which is shared between several processing apparatus. Alternatively, the exhaust device may be a turbopump, roughing pump, cryopump, or other stand-alone vacuum device capable of generating an exhaust flow. The multi-stage flow control apparatus 200 may comprise two stages: a throttle valve stage 204 used to control a desired flow rate or set point from the bowl, and a floating plunger stage 206 used to reduce or eliminate the fluctuations and back streaming from the house exhaust. Of course, there can be other variations, modifications, and alternatives.

Throttle valve stage 204 is coupled with an inlet 202, which receives a flow input from the semiconductor processing chamber. Inlet 202 may be coupled to the semiconductor processing chamber through an exhaust line (not shown). Furthermore, inlet 202 provides an opening to throttle valve stage 204. Throttle valve stage 204 may be shaped in a variety of configurations depending upon the specific implementation. For example, throttle valve stage 204 may include a seat 208 with upward sloping faces. The base of the seat may reveal an internal orifice 210 employed to allow exhaust flow 216 from the semiconductor processing chamber to progress from throttle valve stage 204 to floating plunger stage 206.

Throttle valve stage 204 further includes throttle valve plug 212, which may be controlled by a linear actuator (not shown) to control a desired flow rate or set point from the bowl. Of course, other devices could be used to provide throttle valve plug 212 with a desired range of motion. For example, the linear actuator may be coupled with throttle valve plug 212 at its stem 213 which protrudes from throttle valve stage 204. The desired flow rate may be set by modulating the distance 214 between throttle valve plug 212 and upward sloping faces of seat 208. A larger distance between throttle valve plug 212 and upward sloping faces of seat 208 can allow for an increased flow rate, and a smaller distance between throttle valve plug 212 and upward sloping faces of seat 208 can allow for a reduced flow rate. Throttle valve plug 212 may be modulated by the linear actuator to move in a substantially vertical motion, thus allowing for a varied amount of exhaust flow to progress between throttle valve plug 212 and upward sloping faces of seat 208. In another example, upward sloping faces of seat 208 and the portion of throttle valve plug 212 opposite from upward sloping faces of seat 208 may possess the same gradient to allow for minimal obstruction in the exhaust flow path.

Other throttle configurations could also be used as well, such as a throttle with downwards sloping faces and a similarly shaped throttle valve plugs. However, one additional advantage to utilizing upward sloping faces within throttle valve stage 204 is that the exhaust device (not shown) pulls the throttle valve closed during operation. For example, during conventional operation of the device, the desired flow rates may be low, necessitating a small gap between the throttle valve plug and the faces to restrict exhaust flow. By utilizing the exhaust flow stream to partially close the throttle valve in an upward sloping face design, a reduced amount of force can be expended in setting the desired flow rate for the device.

A floating plunger stage 206 is coupled to throttle valve stage 204, and exhaust flow 216 proceeds from throttle valve stage 204 through floating plunger stage 206 and exits flow control apparatus 200 through an outlet 224. A floating plunger 218 moves vertically to vary the opening to opening 222, with the motion being a function of the weight of floating plunger 218, the pressure in the region 230 below the flexible membrane 220, and the vacuum level above the plunger. Among other functions, floating plunger 218 is designed to reduce or eliminate the fluctuations in the exhaust from an exhaust device and potential back streaming from the exhaust device. An opening 222 may be defined between a top surface of floating plunger 218 and an upper portion of outlet 224. As floating plunger 218 rises in a vertical direction, opening 222 is reduced in size, and opening 222 is enlarged when floating plunger 218 is lowered in a vertical direction. This can greatly reduce the amount of backflow and exhaust that can progress upstream and affect the operation of the semiconductor processing chamber coupled with flow control apparatus 200. In addition, the floating plunger implementation further helps to eliminate variations in the exhaust level by providing a controlled area through which exhaust flow 216 can flow. In addition, if an exhaust device is shared among different processing apparatus, crosstalk between different processing apparatus can also be reduced.

A vent 226 providing a controlled pressure below floating plunger 218 causes the floating plunger 218 to rise to a desired level. Floating plunger 218 may be secured by flexible membranes 220, which may be attached to an interior surface of floating plunger stage 206. Of course, other attachment methods could also be used, such as attaching flexible membrane 220 to posts located on the interior perimeter of floating plunger stage 206. While flexible membrane 220 is shown as having a straight profile, the shape of flexible membrane 220 should not be restricted as thus. For example, flexible membrane 220 may also have a wavy or curved profile. Flexible membrane 220 may be made from a rubber or silicone material that allows the membrane to contract and expand with the movement of floating plunger 218. The stroke of floating plunger 218 may be limited by the size, attachment location, and material of flexible membrane 220. In addition, two separate pressure regions may be maintained within floating plunger stage 206: a first pressure region 228 located above floating plunger 218 and flexible membrane 220, and a second pressure region 230 located below floating plunger 218 and flexible membrane 220. By maintaining a separation between two pressure regions 228 and 230, any particulates generated by controlled pressure through vent 226 being applied to floating plunger 218 can be contained within the second pressure region 230 and prevented from entering exhaust flow 216.

Floating plunger 218 may be made from a variety of materials, including plastic, aluminum, or other lightweight materials that are buoyant under a controlled pressure through vent 226. For example, floating plunger 218 may be hollow so that the weight of the plunger can be modified by partial filling of the plunger with fluids or solids, thereby customizing the plunger to a particular house exhaust.

The movement of floating plunger 218 under the controlled pressure through vent 226 may be in a substantially vertical position. To reduce the size of an opening 222 between a top surface of floating plunger 218 and an upper portion of outlet 224, outlet 224 may be recessed into floating plunger stage 206. By doing so, the horizontal distance between floating plunger 218 and outlet 224 can be reduced and exhaust flows more accurately maintained.

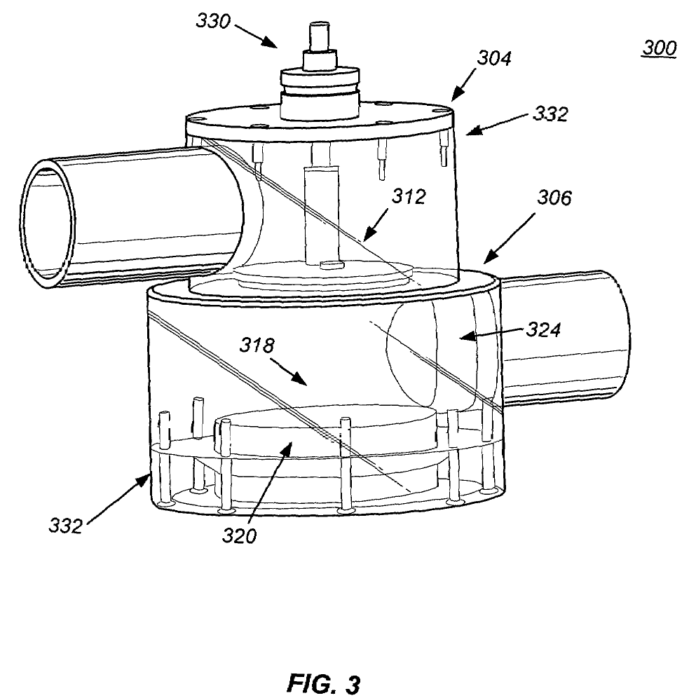

FIG. 3 is a simplified perspective view of a multi-stage flow control apparatus according to an embodiment of the present invention. A flow control apparatus 300 is shown in a 3-dimensional layout. This diagram is merely an example, which should not unduly limit the scope of the claims herein. One of ordinary skill in the art would recognize many other variations, modifications, and alternatives. For example, aspects of flow control apparatus 300 may be similar to flow control apparatus shown in FIG. 2.

Throttle valve stage 304 and floating plunger stage 306 are shown using a dual-wall design where an external layer is used to secure exterior surfaces of the stages together. For example, attaching devices 332 may be used within both stages 304, 306 to attach top and bottom sections to the stages. A separate inside wall within both stages 304, 306 contains the areas through which exhaust will flow within the stages. The addition of a second wall adds to the robustness of the design against physical damage which could cause leakage of the exhaust into the wafer fabrication environment and contamination of the semiconductor processing chamber. Alternatively, a single-wall design could also be used where attaching devices 332 are also contained within the exhaust flow area. Throttle valve plug 312 is attached to a mounting attachment 330, which couples throttle valve plug 312 to a linear actuator (not shown) or other device providing throttle valve plug 312 with a desired range of motion. Additionally, outlet 324 may extend into floating plug stage 306 to allow for a desired opening size between outlet 324 and floating plunger 318 when the floating plunger 318 is extended in a vertical direction. Flexible attachment 320 is shown as securing floating plunger 318 to an inner wall of floating plunger stage 306.

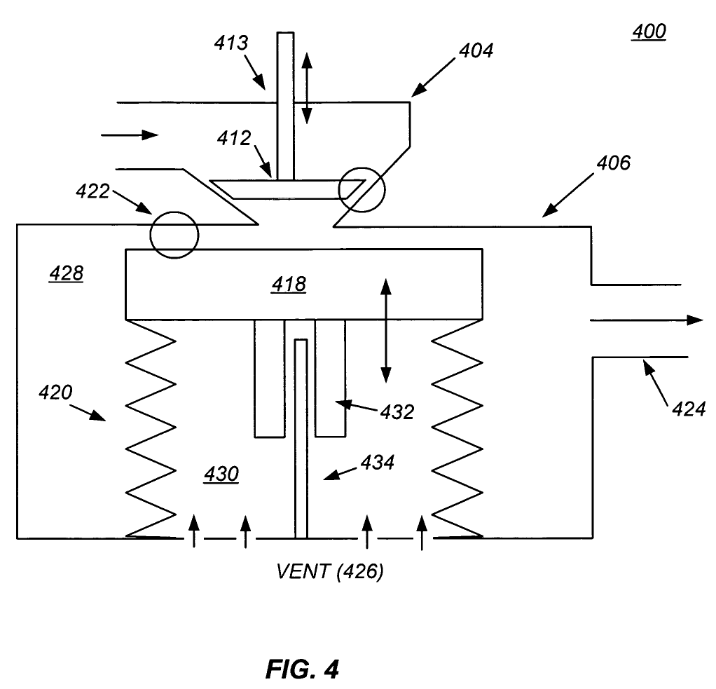

FIG. 4 is a simplified cross-sectional diagram of an multi-stage flow control apparatus according to an additional embodiment of the present invention. This diagram is merely an example, which should not unduly limit the scope of the claims herein. One of ordinary skill in the art would recognize many other variations, modifications, and alternatives. For example, flow control apparatus 400 shown in FIG. 4 may share similar elements with flow control apparatus 200 shown in FIG. 2. Flow control apparatus 400 utilizes a multi-stage design, comprising a throttle valve stage 404 and a floating plunger stage 406. Throttle valve stage 404 and throttle valve plug 412 may provide similar functions to the components described in regards to flow control apparatus 200 shown in FIG. 2. In addition, flow control apparatus 400 could also employ a dual-wall design as shown in FIG. 3.

Floating plunger stage 406 is configured with a floating plunger 418, which may be hollow so that the weight of the plunger can be modified by partial filling of the plunger with fluids or solids, thereby customizing the plunger to a particular house exhaust. However floating plunger 418 is coupled with a surface of floating plunger stage 406 through flexible membrane 420. Flexible membrane 420 utilizes an accordion-style design which allows the membrane to expand and contract to accommodate variable amounts of controlled pressure through vent 426. For example, the membrane may be made of silicone, rubber, or other nonpermeable materials. In addition, the stroke of floating plunger 418 is not limited by the material properties of the material chosen for flexible membrane 420, as additional amounts of the material may be incorporated within flexible membrane 420 to allow floating plunger 418 to achieve its full stroke. For example, the stroke of floating plunger 418 may extend to a top face of floating plunger stage 406. Two different pressure regions 430 and 428 are provided, with pressure region 428 above and to the sides of flexible membrane 420 and floating plunger 418, and pressure region 430 below and contained by floating membrane 420 and floating plunger 418. This can allow for improved particulate content within the exhaust flow, as any particulates generated by controlled pressure through vent 426 are maintained within pressure region 430.

The opening 422 being varied by the movement of floating plunger 418 may between an upper inwards surface of floating plunger stage 406 and a top surface of floating plunger 418. For example, a floating plunger 418 may have a large top surface area to guide exhaust flow in a more controlled manner. As the movement of the opening 422 between the floating plunger 418 and a surface of floating plunger stage 406 occurs away from outlet 424, recession of outlet 424 into floating plunger stage 406 is no longer needed.

A guide pin 434 may be employed to improve the lateral stability of floating plunger 418. During operation, floating plunger 418 may shift laterally during operation, which can detract from the flow control of the exhaust. Guide pin 434 and guide pin housing 432 are included to ensure that the motion of floating plunger 418 is maintained in a substantially vertical direction. Guide pin 434 may be coupled to a lower face of floating plunger stage 406, and guide pin housing 432 may be coupled to a bottom face of floating plunger 418. Guide pin housing 432 and guide pin 434 are coupled together to allow for a minimum amount of lateral motion while ensuring floating plunger 418 can extend to its full stroke.

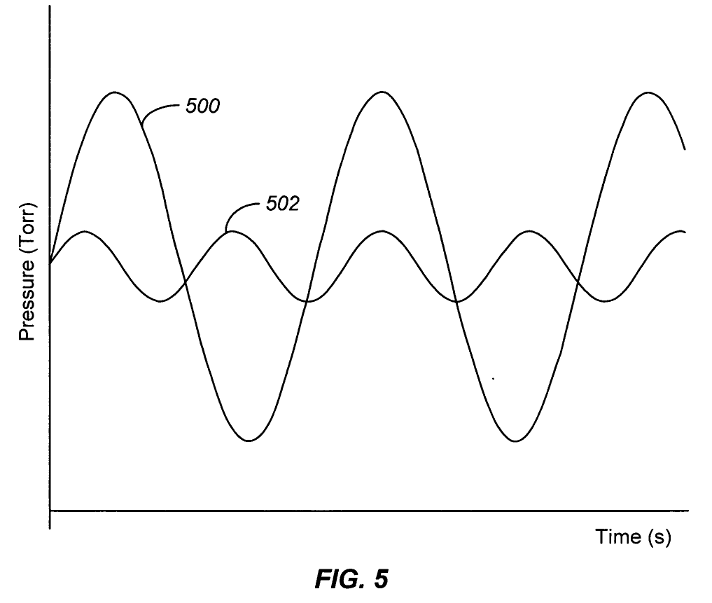

FIG. 5 is a simplified exemplary diagram showing exhaust pressure as a function of time with and without a multi-stage flow control apparatus according to an embodiment of the present invention. This diagram is merely an example, which should not unduly limit the scope of the claims herein. One of ordinary skill in the art would recognize many other variations, modifications, and alternatives. Signal 500 shows the exhaust pressure vs. time for the exhaust of a semiconductor processing chamber without a flow controlled valve during operation. As an example, the exhaust pressure represented by the signal may be measured at the inlet of inlet 202 as shown in FIG. 2. Signal 502, in comparison, shows the exhaust pressure vs. time for the exhaust of a semiconductor processing chamber with a flow controlled valve during operation. The amount of fluctuation within the exhaust pressure can be greatly minimized and the pressure cycles can be greatly reduced due to the dampening effect of a flow control apparatus on exhaust flow according to an embodiment of the present invention.

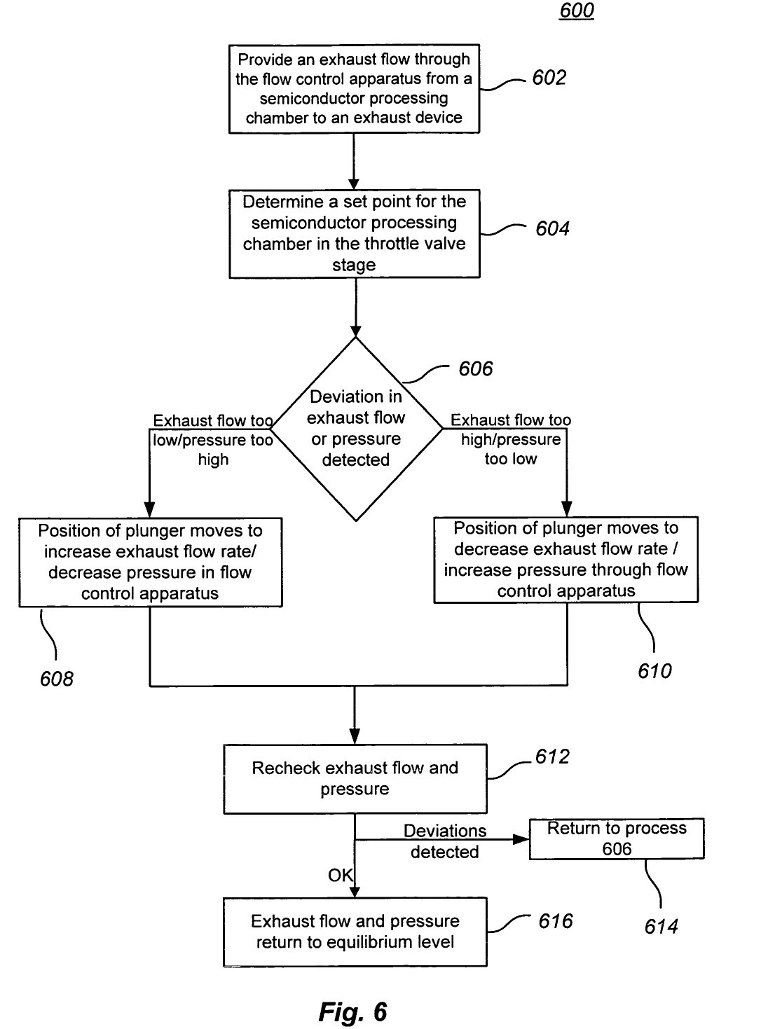

FIG. 6 is a simplified exemplary process flow showing processes used to maintain a constant exhaust flow according to an embodiment of the present invention. This diagram is merely an example, which should not unduly limit the scope of the claims herein. One of ordinary skill in the art would recognize many other variations, modifications, and alternatives. Process flow 600 includes process 602 for providing an exhaust flow through the multi-stage flow control apparatus from a semiconductor processing chamber to a exhaust device, process 604 for determining a set point for the semiconductor processing chamber in the throttle valve stage, process 606 for detecting a deviation in the exhaust flow or pressure, process 608 for moving the position of the plunger to increase the exhaust flow rate and/or decrease pressure in the flow control apparatus, process 610 for moving the position of the plunger to decrease the exhaust flow rate and/or decrease the pressure in the flow control apparatus, process 612 for rechecking the exhaust flow, process 614 for returning to process 606, and process 616 for returning the exhaust flow to equilibrium. For example, process flow 600 may be used in conjunction with the flow control apparatus shown in FIGS. 2-4.

In process 602, an exhaust flow is provided through a flow control apparatus from a semiconductor processing chamber to an exhaust device. During this process, the exhaust flow level through the flow control apparatus is monitored on a periodic or continuous basis to detect variations or deviations from a predetermined exhaust flow level. For example, the exhaust flow rate may be monitored to determine if the measured exhaust flow rate is outside a predetermined window of desired exhaust flow rates. The monitoring can take place at the semiconductor processing chamber, within either stage of the flow control apparatus, or within an exhaust line coupling the semiconductor processing chamber to the flow control apparatus. In an embodiment, a flow or pressure monitor may be utilized to monitor the exhaust flow level through or pressure within the flow control apparatus. In process 604, a set point is determined for the semiconductor processing chamber within the throttle valve stage in the flow control apparatus. When a change, for example, a deviation of exhaust flow rate greater than the desired variability defined by the predetermined window, is detected in the exhaust flow in process 606, steps are taken to address the variation. In addition, the pressure within the flow control apparatus may also be monitored to determine if a deviation in pressure greater than the desired variability defined by the predetermined window is detected. For example, the exhaust flow and pressure may be monitored concurrently with each other.

If the exhaust flow is too low or the pressure within the flow control apparatus is too high, the position of the plunger shifts to increase the exhaust flow rate through the flow control apparatus and/or decrease the pressure in the flow control apparatus in process 608. For example, the floating plunger may be lowered to increase the opening between the top surface of the floating plunger and an upper portion of the output tube in accordance with an embodiment of the invention shown in FIG. 2. Alternatively, the floating plunger may be lowered to increase the opening between the top surface of the floating plunger and a top surface of the floating plunger stage in accordance with an embodiment of the invention shown in FIG. 4. This process may self-regulated by the flow control apparatus without any direct control from a user. For example, control of the vent or applied pressure used to move the floating plunger may be coupled to the pressure and exhaust monitors coupled with the flow control apparatus to form a self-regulated monitoring loop. By coupling these items together, pressure and exhaust flow deviations can be reduced to lower levels by the flow control apparatus.

If the exhaust flow is too high or the pressure within the flow control apparatus is too low, the position of the plunger shifts to decrease the exhaust flow rate through the flow control apparatus and/or increase the pressure in the flow control apparatus in process 610. For example, the floating plunger may be raised to decrease the opening between the top surface of the floating plunger and an upper portion of the output tube in accordance with an embodiment of the invention shown in FIG. 2. Alternatively, the floating plunger may be raised to decrease the opening between the top surface of the floating plunger and a top surface of the floating plunger stage in accordance with an embodiment of the invention shown in FIG. 4. This process may self-regulated by the flow control apparatus without any direct control from a user. For example, control of the vent or applied pressure used to move the floating plunger may be coupled to the pressure and exhaust monitors coupled with the flow control apparatus to form a self-regulated monitoring loop. By coupling these items together, pressure and exhaust flow deviations can be reduced to lower levels by the flow control apparatus.

In process 612, the exhaust flow and pressure are rechecked to ensure that any deviation in exhaust flow or pressure has subsided to be within a predetermined window. If so, the exhaust flow and pressure return to an acceptable equilibrium level in process 616. If deviations are still detected, the system returns to process 606 until an equilibrium level is reached.

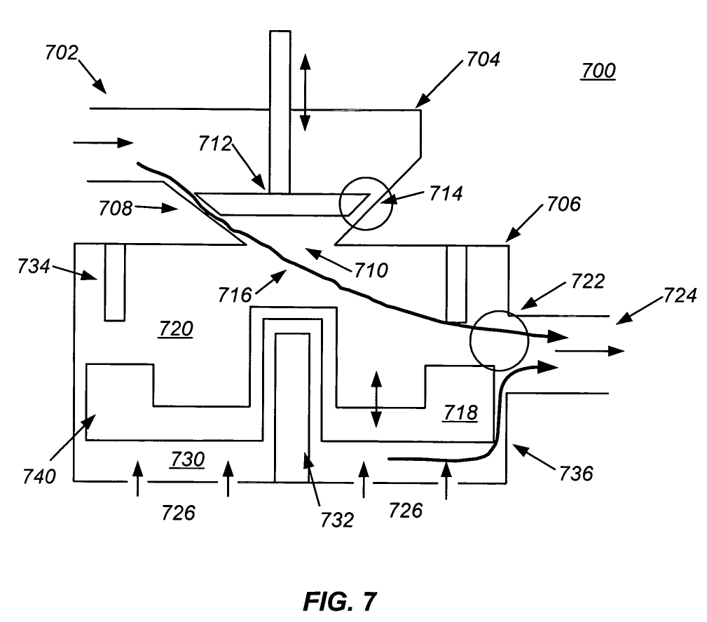

FIG. 7 is a simplified cross-sectional diagram of a multi-stage flow control apparatus according to an embodiment of the present invention. This diagram is merely an example, which should not unduly limit the scope of the claims herein. One of ordinary skill in the art would recognize many other variations, modifications, and alternatives. A multi-stage flow control apparatus 700 is provided for use between a semiconductor processing chamber (not shown) and an exhaust device (not shown). For example, the semiconductor processing chamber may be a lithography device including one or more bowls used within lithography processing steps such as a track lithography tool described in FIG. 1. In another example, the exhaust device may be house exhaust present in a semiconductor manufacturing facility which is shared between several processing apparatus. Alternatively, the exhaust device may be a turbopump, roughing pump, cryopump, or other stand-alone vacuum device capable of generating an exhaust flow. The multi-stage flow control apparatus 700 may comprise two stages: a throttle valve stage 704 used to control a desired flow rate or set point from the bowl, and a floating plunger stage 706 used to reduce or eliminate the fluctuations and back streaming from the house exhaust. Of course, there can be other variations, modifications, and alternatives.

The design of throttle valve stage 704 may be similar to that of throttle valve stages 204 and 404. For example, throttle valve stage 704 is coupled with an inlet 702, which receives a flow input from the semiconductor processing chamber. Furthermore, inlet 702 provides an opening to throttle valve stage 704. Throttle valve stage 704 may be shaped in a variety of configurations depending upon the specific implementation. For example, throttle valve stage 704 may include a seat 708 with upward sloping faces. The base of the seat 708 may reveal an internal orifice 710 employed to allow exhaust flow 716 from the semiconductor processing chamber to progress from throttle valve stage 704 to floating plunger stage 706.

Throttle valve stage 704 further includes throttle valve plug 712, which may be controlled by a linear actuator (not shown) to control a desired flow rate or set point from the bowl. Of course, other devices could be used to provide throttle valve plug 712 with a desired range of motion. For example, the linear actuator may be coupled with throttle valve plug 712 at its stem 713 which protrudes from throttle valve stage 704. The desired flow rate may be set by modulating the distance 714 between throttle valve plug 712 and upward sloping faces of seat 708. A larger distance between throttle valve plug 712 and upward sloping faces of seat 708 can allow for an increased flow rate, and a smaller distance between throttle valve plug 712 and upward sloping faces of seat 708 can allow for a reduced flow rate. Throttle valve plug 712 may be modulated by the linear actuator to move in a substantially vertical motion, thus allowing for a varied amount of exhaust flow to progress between throttle valve plug 712 and upward sloping faces of seat 708. In another example, upward sloping faces of seat 708 and the portion of throttle valve plug 712 opposite from upward sloping faces of seat 708 may possess the same gradient to allow for minimal obstruction in the exhaust flow path.

Other throttle configurations could also be used as well, such as a throttle with downwards sloping faces and a similarly shaped throttle valve plugs. However, one additional advantage to utilizing upward sloping faces within throttle valve stage 704 is that the exhaust device (not shown) pulls the throttle valve closed during operation. For example, during conventional operation of the device, the desired flow rates may be low, necessitating a small gap between the throttle valve plug and the faces to restrict exhaust flow. By utilizing the exhaust flow stream to partially close the throttle valve in an upward sloping face design, a reduced amount of force can be expended in setting the desired flow rate for the device.

A floating plunger stage 706 is coupled to throttle valve stage 704, and exhaust flow 716 proceeds from throttle valve stage 704 through floating plunger stage 706 and exits flow control apparatus 700 through an outlet 724. A floating plunger 718 moves vertically to vary the opening 722 to outlet 724, with the motion being a function of the weight of floating plunger 718, the pressure in the region 730 below the floating plunger 718, and the vacuum level above the floating plunger 718. Among other functions, floating plunger 718 is designed to reduce or eliminate the fluctuations in the exhaust from an exhaust device and potential back streaming from the exhaust device. An opening 722 may be defined between a top surface of floating plunger 718 and outlet 724. As floating plunger 718 rises in a vertical direction, opening 722 is reduced in size, and opening 722 is enlarged when plunger 718 is lowered in a vertical direction. This can greatly reduce the amount of backflow and exhaust that can progress upstream and affect the operation of the semiconductor processing chamber coupled with flow control apparatus 700. In addition, the floating plunger implementation further helps to eliminate variations in the exhaust level by providing a controlled area through which exhaust 716 can flow. In addition, if an exhaust device is shared among different processing apparatus, crosstalk between different processing apparatus can also be reduced.

A vent 726 providing a controlled pressure below floating plunger 718 causes the floating plunger 718 to rise to a desired level. Floating plunger 718 may float and not be in contact with any other surfaces during operation of flow control apparatus 700 when a controlled pressure is applied through vent 726. Floating plunger 718 may have a primarily flat surface facing the lower surface of floating plunger stage 706 to optimize the upwards movement of floating plunger 718 in response to the applied pressure through vent 726. Side regions 740 of floating plunger 718 may be elevated on one or both sides to reduce the amount of movement of floating plunger 718 needed to close opening 722. Of course, there can be other variations, modifications, and alternatives.

Floating plunger 718 may be centered upon a guide pin 732, which may be attached to an interior surface of floating plunger stage 706. For example, floating plunger 718 may be designed so that at least a portion of its surface is elevated to accommodate guide pin 732. Of course, other attachment methods could also be used, such utilizing a multiple guide pin design. The inclusion of guide pin 732 within floating plunger stage 706 allows for floating plunger 718 to move in a substantially vertical direction without incurring lateral or rotational movement. A physical coupling may be made between floating plunger 718 and guide pin 732, or a gap maintained between guide pin 732 and floating plunger 718 that is closed when floating plunger 718 experiences lateral or rotational movement. For example, floating plunger 718 may rest upon guide pin 732 when no controlled pressure is provided through vent 726. Alternatively, guide pin 732 may also protrude from floating plunger 718. Support posts 734 may be provided to prevent floating plunger 718 from contacting a top surface of floating plunger stage 706. For example, support posts 734 may be coupled to an interior surface of floating plunger stage 706. For example, support posts 734 may be made from an rubber or soft material that allows for contact with floating plunger 718 without damage. In addition, the height of support post 734 may be set to provide an upper limit for the stroke of floating plunger 718. Correspondingly, the height of guide pin 732 may be set to provide a lower limit for the stroke of floating plunger 718. For example, the upper and lower limits of floating plunger 718 may be correspond with the upper and lower surfaces of outlet 724. Of course, there can be other variations, modifications, and alternatives.

A small gap 736 may be present between floating plunger 718 and a side surface of floating plunger stage 706. Unlike the embodiments described in regards to FIGS. 2 and 4, a separate vacuum is not maintained above and below floating plunger 718. Instead, gas can flow from below floating plunger 718 through gap 736. The gas can then be exhausted through outlet 724 to leave flow control apparatus 700. A pressure differential Δp is present between region 730 and region 720, as a result of the gap 736 and controlled pressure through vent 726 being applied to the bottom of floating plunger 718. The size of the gap 736 must be chosen to fit the desired flow characteristics of the flow control apparatus, as a gap 736 that is too large will not maintain a pressure differential Δp above and below the floating plunger 718 due to large outflows through gap 736. Additionally, a overly large gap 736 can also lead to increased particulates moving through vent 726 reaching into region 720 above floating plunger 718. An additional benefit towards having a flow of gas through gap 736 is that it can contribute to the lateral stability of floating plunger 718 in operation. Of course, there can be other variations, modifications, and alternatives.

Floating plunger 718 may be made from a variety of materials, including plastic, aluminum, or other lightweight materials that are buoyant under a controlled pressure through vent 726. For example, floating plunger 718 may be hollow so that the weight of the plunger can be modified by partial filling of the plunger with fluids or solids, thereby customizing the plunger to a particular house exhaust.

The movement of floating plunger 718 under controlled pressure through vent 726 may be in a substantially vertical position. To reduce the size of an opening 722 between a top surface of floating plunger 718 and an upper portion of outlet 724, outlet 724 may be recessed into floating plunger stage 706. By doing so, the horizontal distance between floating plunger 718 and outlet 724 can be reduced and exhaust flows more accurately maintained.

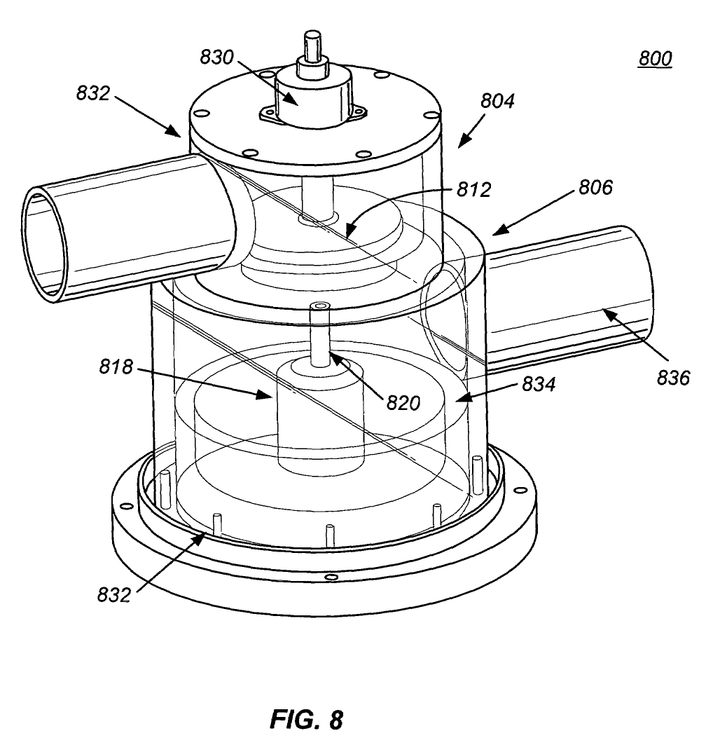

FIG. 8 is a simplified perspective view of a multi-stage flow control apparatus according to an embodiment of the present invention. This diagram is merely an example, which should not unduly limit the scope of the claims herein. One of ordinary skill in the art would recognize many other variations, modifications, and alternatives. For example, aspects of flow control apparatus 800 may be similar to flow control apparatus shown in FIG. 7 and FIG. 3.

Throttle valve stage 804 and floating plunger stage 806 are shown using a dual-wall design where an external layer is used to secure exterior surfaces of the stages together. For example, attaching devices 832 may be used within both stages 804, 806 to attach top and bottom sections to the stages. A separate inside wall within both stages 804, 806 contains the areas through which exhaust will flow within the stages. The addition of a second wall adds to the robustness of the design against physical damage which could cause leakage of the exhaust into the wafer fabrication environment and contamination of the semiconductor processing chamber. Alternatively, a single-wall design could also be used where attaching devices 832 are also contained within the exhaust flow area.

Throttle valve plug 812 is attached to a mounting attachment 830, which couples throttle valve plug 812 to a linear actuator (not shown) or other device providing throttle valve plug 812 with a desired range of motion. In addition, guide pin 820 is shown coupled to floating plunger 818 to restrict the lateral or rotational movement of floating plunger 818 and allow floating plunger 818 to move in a substantially vertical direction. Floating plunger 818 is also shown within its rest position, where no pressure is provided underneath floating plunger 818 to move floating plunger 818 in a substantially vertical direction. For example, the position of side regions 834 of floating plunger 818 may be below an inner orifice of outlet 836 at the rest position so that when pressure is applied to floating plunger 818, the exhaust flow through outlet 836 may be controlled. Of course, there can be other variations, modifications, and alternatives.

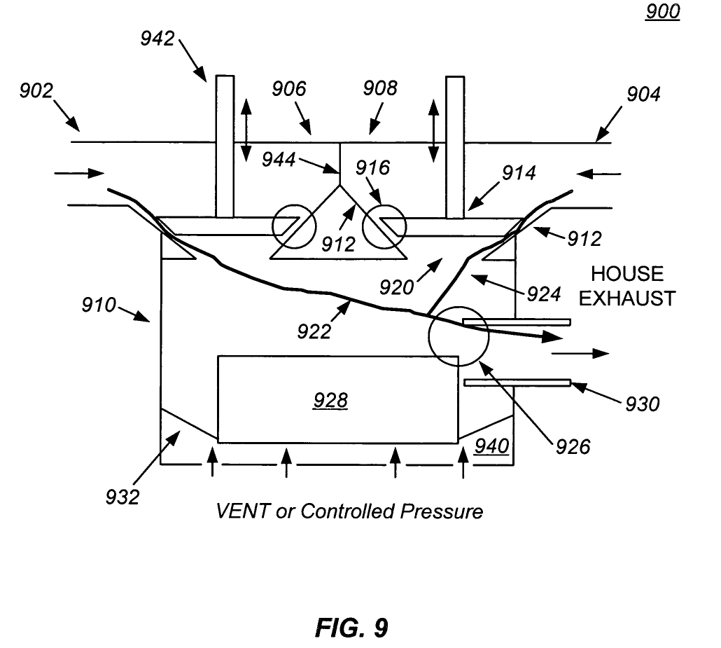

FIG. 9 is a simplified cross-sectional diagram of a multi-stage flow control apparatus according to another embodiment of the present invention. This diagram is merely an example, which should not unduly limit the scope of the claims herein. One of ordinary skill in the art would recognize many other variations, modifications, and alternatives. For example, aspects of the multi-stage flow control apparatus 900 may be similar to other flow control apparatus such as those described previously within the specification or otherwise.

Multi-stage flow control apparatus 900 includes first and second throttle valve stages 906, 908, which are coupled respectively to inlets 902, 904 and floating plunger stage 910. For example, throttle valve stages 906, 908 may be similar to throttle valve stages described in regards to previous drawings. Inlet 902 receives a flow input from a first semiconductor processing chamber (not shown) and inlet 904 receives a flow input from a second semiconductor processing chamber (not shown). Inlets 902, 904 may be coupled to the semiconductor processing chambers through an exhaust line (not shown). Furthermore, inlets 902, 904 additionally provide an opening to throttle valves stages 906, 908. Throttle valve stages 906, 908 may be shaped in a variety of configurations depending upon the specific implementation. For example, throttle valve stages 906, 908 may include seats 912 with upward sloping faces. The base of seats 912 may reveal an internal orifice 920 employed to allow exhaust flows 922, 924 from the first and second semiconductor processing chambers, respectively, to progress from throttle valve stages 906, 908 to floating plunger stage 910. Throttle valve stages 906, 908 may additionally share a common wall 944 between the two stages.

Throttle valve stages 906, 908 further includes throttle valve plugs 914, which may be controlled by linear actuators (not shown) to control a desired flow rate or set point from the bowls within the semiconductor processing chamber. Of course, other devices could be used to provide throttle valve plugs 914 with a desired range of motion. For example, the linear actuators may be coupled with throttle valve plugs 914 at their stems 942 which protrude from throttle valve stages 906, 908. The desired flow rates for each chamber may be set by modulating the distance 916 between throttle valve plugs 914 and upward sloping faces of seats 912. A larger distance between throttle valve plugs 914 and upward sloping faces of seats 912 can allow for increased flow rates, and a smaller distance between throttle valve plugs 914 and upward sloping faces of seats 912 can allow for a reduced flow rate. Throttle valve plug 914 may be modulated by the linear actuator to move in a substantially vertical motion, thus allowing for a varied amount of exhaust flow to progress between throttle valve plugs 914 and upward sloping faces of seats 912. In another example, upward sloping faces of seats 912 and the portion of throttle valve plug 914 opposite from upward sloping faces of seats 912 may possess the same gradient to allow for minimal obstruction in the exhaust flow path.

Throttle valve stages 906 and 908 are coupled to floating plunger stage 910. For example, floating plunger stage 910 includes floating plunger 928, flexible membrane 932, and outlet 930. For example, exhaust flows 922, 924 proceed from throttle valve stages 906, 908 through floating plunger stage 910 and exit flow control apparatus 900 through an outlet 930. For example, the first and second exhaust flows may be combined together within floating plunger stage 910 before exiting through outlet 930. Floating plunger 928 moves vertically to vary the opening 926 to outlet 930, with the motion being a function of the weight of floating plunger 928, the pressure in the region 940 below the flexible membrane 932, and the vacuum level above the plunger. Among other functions, floating plunger 928 is designed to reduce or eliminate the fluctuations in the exhaust from an exhaust device and potential back streaming from the exhaust device. For example, the floating plunger stage 910 shown within FIG. 9 may be similar to floating plunger stage 206 within FIG. 2, and further description of similar components is omitted. However, other floating plunger stage designs may also be used within multi-stage flow control apparatus 900 with no detriment to its operation, such as those described previously within the specification or otherwise.

One advantage of utilizing a dual input design coupled to two or more semiconductor processing chambers as illustrated in FIG. 9 is that the floating plunger within the flow control apparatus is shared by the two throttle valves to reduce the footprint and system cost. Instead of providing two separate flow control apparatus, one flow control apparatus with multiple inputs can be used. Additionally, the use of two throttle valves and a single plunger allows for two disparate set points to be maintained for each semiconductor processing chamber depending upon the specific process conditions. Alternatively, the set points for chambers may set to the same value. For bowl designs with shared dispense or other twin designs, pressure and exhaust flow within each chamber may be independently controlled by the operation of the throttle valve stages.

While embodiments of the present invention have been described in regards to a dual-output design, multiple-output designs could also be utilized to accommodate more than two semiconductor processing chambers. In addition, throttle valve stages 906, 908 may be different from each other by utilizing alternative throttle valve configurations, different chamber shapes, or a different interface between the throttle valve plugs 914 and sloping faces of seats 912. For example, downwards sloping faces could also be used within the throttle valve stages 906, 908.

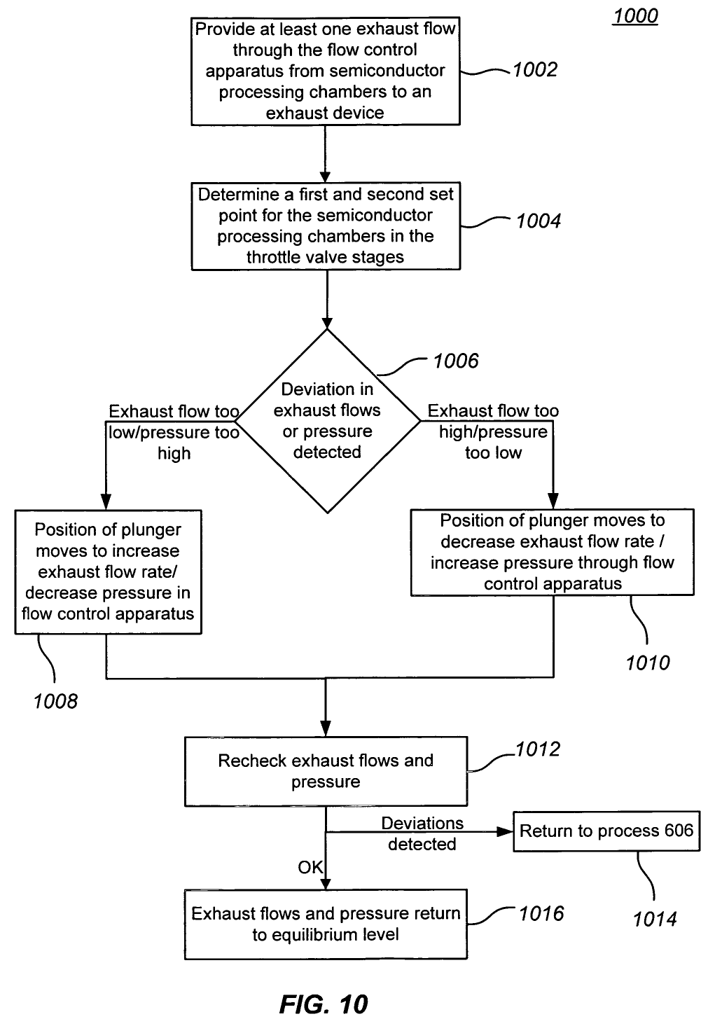

FIG. 10 is a simplified exemplary process flow showing processes used to maintain a constant exhaust flow according to another embodiment of the present invention. This diagram is merely an example, which should not unduly limit the scope of the claims herein. One of ordinary skill in the art would recognize many other variations, modifications, and alternatives. Process flow 1000 includes process 1002 for providing at least one exhaust flows through the flow control apparatus from semiconductor processing chambers to an exhaust device, process 1004 for determining first and second set points for the semiconductor processing chambers in the throttle valve stages, process 1006 for detecting a deviation in the exhaust flows or pressure, process 1008 for moving the position of a plunger to increase the exhaust flow rate and/or decrease pressure in the flow control apparatus, process 1010 for moving the position of the plunger to decrease the exhaust flow rate and/or decrease the pressure in the flow control apparatus, process 1012 for rechecking the exhaust flows, process 1014 for returning to process 1006, and process 1016 for returning the exhaust flow to equilibrium. For example, process flow 1000 may be used in conjunction with the flow control apparatus shown in FIG. 9.

In process 1002, at least one exhaust flow is provided which flow through the flow control apparatus through semiconductor processing chambers to an exhaust device. During this process, the exhaust flow levels through the flow control apparatus are monitored on a periodic or continuous basis to detect variations or deviations from a predetermined exhaust flow level. For example, the exhaust flow rates may be monitored to determine if the measured exhaust flow rates are outside a predetermined window of desired exhaust flow rates. The monitoring can take place at the semiconductor processing chamber, within any stage of the flow control apparatus, or within an exhaust line coupling the semiconductor processing chamber to the flow control apparatus. In an embodiment, a flow or pressure monitor may be utilized to monitor the exhaust flow level through or pressure within the flow control apparatus. This pressure monitor or sensor may be coupled with the floating plunger and can also be used to detect if the house exhaust has failed and the house exhaust is at atmosphere. In this case, there will not be any vacuum above the plunger and the weight of the floating plunger will cause the plunger to settle at the bottom of the chamber if a vent or controlled pressure is not continuously applied.

In another alternative embodiment, only a first exhaust flow is provided without the second exhaust flow. Referring to FIG. 9, closing of one of the throttle valve stages would produce this situation. For example, if only one exhaust flow is provided through a throttle valve stage, the flow control apparatus may still function with the other throttle valve closed.

In process 1004, set points are determined for the semiconductor processing chambers within the throttle valve stages in the flow control apparatus. For example, the set points within each of the throttle valve stage may be set independently of each other, thus allowing for different exhaust flows from the semiconductor processing chambers. It may be desirable for a first chamber to have a high set point, thus allowing a large amount of exhaust to flow through the first throttle valve stage coupled to the first chamber, while the second chamber has a low set point and a lesser amount of exhaust flowing through the second throttle valve stage coupled with the second chamber.

When a change, for example, a deviation of the exhaust flow rate greater than the desired variability defined by the predetermined window, is detected in the exhaust flow in process 1006, steps are taken to address the variation. In addition, the pressure within the flow control apparatus may also be monitored to determine if a deviation in pressure greater than the desired variability defined by the predetermined window is detected. For example, the exhaust flow and pressure may be monitored concurrently with each other.

Processes 1006-1016 are similar to processes 606-616 and the description of processes 606-616 may also be used for processes 1006-1016. Of course, small variations in the processes may occur due to the presence of two or more throttle valve stages within the flow control apparatus. Of course, there can be other variations, modifications, and alternatives.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A multi-stage flow control apparatus for use during the processing of a semiconductor substrate, the multi-stage flow control apparatus comprising:
a first inlet and a second inlet;
an outlet;
a first throttle valve stage coupled to the first inlet, the first throttle valve stage comprising
a first throttle valve plug located within the first throttle valve stage, the first throttle valve plug configured to control the amount of airflow through the first throttle valve stage by modulating the distance between the first throttle valve plug and faces of the first throttle valve stage;
a second throttle valve stage coupled to the second inlet, the second throttle valve stage comprising
a second throttle valve plug located within the second throttle valve stage, the second throttle valve plug configured to control the amount of airflow through the second throttle valve stage by modulating the distance between the second throttle valve plug and faces of the second throttle valve stage; and
a floating plunger stage coupled to the throttle valve stage.

2. The multi-stage flow control apparatus of claim 1 wherein the floating plunger stage comprises
a floating plunger, a surface of the floating plunger receiving a controlled pressure which allows the floating plunger to move and vary an opening between the floating plunger and the outlet; and
a guide pin, the guide pin configured to restrict the movement of the floating plunger to a substantially vertical direction.

3. The multi-stage flow control apparatus of claim 1 wherein the floating plunger stage comprises
a floating plunger coupled to a flexible attachment, the flexible attachment allowing the floating plunger to move in a controlled manner to vary an opening between the floating plunger and the outlet.

4. The multi-stage flow control apparatus of claim 1 wherein the floating plunger stage comprises
a floating plunger coupled to a flexible attachment, the flexible attachment allowing the floating plunger to move in a controlled manner to vary an opening between the floating plunger and the floating plunger stage.

5. The multi-stage flow control apparatus of claim 1 wherein the inlet is coupled with an exhaust output from a semiconductor processing chamber.

6. The multi-stage flow control apparatus of claim 1 wherein the outlet is coupled to an exhaust device, the exhaust device providing an exhaust flow through the outlet.

7. The multi-stage flow control apparatus of claim 6 wherein the exhaust device is house exhaust.

8. The multi-stage flow control apparatus of claim 1 wherein the faces of at least one of the throttle valve stages are upward sloping faces.

9. The multi-stage flow control apparatus of claim 1 wherein set points for the first and second throttle valve stages are set at different values.

10. The multi-stage flow control apparatus of claim 1 further comprising a sensor located within the floating plunger stage to detect an amount of exhaust flow through the flow control apparatus.

11. The multi-stage flow control apparatus of claim 10 wherein the sensor is coupled to a floating plunger.

12. A flow control apparatus comprising:
a first chamber having an inlet and an outlet;
a second chamber having an inlet and an outlet;
a third chamber having at least two inlets and an outlet, a first inlet of the third chamber coupled to the outlet of the first chamber and a second inlet of the third chamber coupled to the outlet of the second chamber;
a first throttle valve operatively coupled to restrict airflow through the first chamber;
a second throttle valve operatively coupled to restrict airflow through the second chamber; and
a floating plunger coupled to restrict airflow through the third chamber, a surface of the floating plunger receiving a controlled pressure that allows the floating plunger to move in a controlled manner.

13. The flow control apparatus of claim 12 further comprising a guide pin configured to restrict the movement of the floating plunger to a substantially vertical direction.

14. The flow control apparatus of claim 12 wherein the first and second chambers are adjacent to each other.

15. The flow control apparatus of claim 12 wherein the position of the first throttle valve is used to determine a first set point for a first semiconductor processing chamber coupled to the flow control apparatus; and
the position of the second throttle valve is used to determine a second set point for a second semiconductor processing chamber coupled to the flow control apparatus.

16. The flow control apparatus of claim 15 wherein the first and second set points are set at different values.

17. The flow control apparatus of claim 12 further comprising a sensor located within the third chamber to detect an amount of exhaust flow through the flow control apparatus.

18. The flow control apparatus of claim 16 wherein the sensor is coupled to the floating plunger.

19. A track lithography tool comprising:
first and second semiconductor processing chambers,
first and second exhaust outputs, the first semiconductor processing chamber coupled to the first exhaust output and the second semiconductor processing chamber coupled to the second exhaust output;
an exhaust device; and
a multi-stage flow control apparatus, wherein the multi-stage flow control apparatus comprises:
a first chamber having an inlet and an outlet;
a second chamber having an inlet and an outlet;
a third chamber having at least two inlets and an outlet, a first inlet of the third chamber coupled to the outlet of the first chamber and a second inlet of the third chamber coupled to the outlet of the second chamber;
a first throttle valve operatively coupled to restrict airflow through the first chamber;
a second throttle valve operatively coupled to restrict airflow through the second chamber; and
a floating plunger coupled to restrict airflow through the third chamber, a surface of the floating plunger receiving a controlled pressure that allows the floating plunger to move in a controlled manner.

20. The track lithography tool of claim 19 wherein the first exhaust output is coupled to the inlet of the first chamber, and the second exhaust output is coupled to the inlet of the second chamber.

21. The track lithography tool of claim 19 wherein the position of the first throttle valve is used to determine a first set point for the first semiconductor processing chamber coupled to the flow control apparatus; and
the position of the second throttle valve is used to determine a second set point for the second semiconductor processing chamber coupled to the flow control apparatus.

22. The track lithography tool of claim 21 wherein the first and second set points are set at different values.

23. A method of operating a multi-stage flow control apparatus comprising:
providing at least one exhaust flow through the multi-stage flow control apparatus from a first semiconductor processing chamber to an exhaust device;
determining a first set point for the first semiconductor processing chamber in a first throttle valve stage;
determining a second set point for the second semiconductor processing chamber in a second throttle valve stage;
detecting a change in the at least one exhaust flow or pressure in the multi-stage flow control apparatus;
varying the position of a floating plunger to modify the at least one exhaust flow or pressure in the multi-stage flow control apparatus;
rechecking the at least one exhaust flow and pressure in the multi-stage flow control apparatus; and
having the at least one exhaust flow and pressure return to an equilibrium flow level.

24. The method of claim 23 wherein the first and second set points are set at different values.

25. The method of claim 23 wherein the at least one exhaust flow comprises a first exhaust flow and a second exhaust flow which have different exhaust levels.
